(19) United States
(12) Patent Application Publication
(10) Pub. No.: US 2026/0264195 A1
(43) Pub. Date: Sep. 10, 2026

(54) POLISHING APPARATUS AND POLISHING TABLE

(71) Applicant: MICRO ENGINEERING, INC., Tokyo (JP)

(72) Inventors: Akio KOMURA, Osaka (JP); Takafumi KUWANO, Tokyo (JP); Hajime TOMIZAWA, Tokyo (JP)

(21) Appl. No.: 19/163,244

(22) PCT Filed: Mar. 9, 2023
(86) PCT No.: PCT/JP2023/009138

§ 371 Date: Sep. 8, 2025

(51) Int. Cl. B24B 55/02; B24B 37/20; B24B 37/34

(52) U.S. Cl. CPC B24B 55/02; B24B 37/20; B24B 37/34

(57) ABSTRACT

There is provided a polishing processing apparatus capable of effectively preventing deformation (thermal deformation) of a polishing platen of a CMP apparatus, further improving the SFOR of a substrate surface and the like, and stably performing polishing processing for a large number of pieces with high quality.

A polishing table 11 includes a polishing platen 1 having a surface on which a polishing pad is disposed, a cooling base 2 on which the polishing platen is placed, and that has first grooves formed in a surface that contacts a rear surface of the polishing platen, and a decompression cooling mechanism 200 that supplies a temperature-controlled negative pressure fluid to the first grooves 21 of the cooling base to simultaneously perform suction and cooling of the polishing platen, collects the negative pressure fluid that has passed through the first grooves to perform chiller treatment, and supplies the negative pressure fluid to the first grooves again. The decompression cooling mechanism includes a vacuum pump 70 that generates the negative pressure fluid, a chiller device 62 that performs chiller cooling of the negative pressure fluid, and a fluid pump 61 that supplies the temperature-controlled negative pressure fluid to the first grooves.

The present application is a U.S. National Phase of International Application Number PCT/JP2023/009138, filed Mar. 9, 2023.

### TECHNICAL FIELD

The present invention relates to a polishing processing apparatus used for polishing processing of substrates such as semiconductor wafers or glass substrates.

### BACKGROUND ART

In recent years, in the manufacturing process of semiconductor devices, as the integration of substrates (hereinafter referred to as wafers) such as semiconductor wafers and glass substrates is increased, planarization techniques for substrate surfaces are becoming increasingly important. Among the planarization techniques, the most important technique is chemical mechanical polishing (CMP). This chemical mechanical polishing uses a polishing processing apparatus (also called a polishing apparatus) to perform polishing processing by bringing a substrate into sliding contact with a polishing surface, while supplying polishing liquid containing abrasive grains such as silica (SiO2) on a polishing surface such as a polishing pad. Hereinafter, this apparatus may also be called a CMP apparatus.

For example, a CMP apparatus disclosed in Patent Literature 1 prevents thermal deformation of a polishing platen onto which a polishing pad is to be attached. A low expansion Invar material is used for a starting material, and control is performed with sophisticated and complex techniques such as devising cooling water channels, temperature management, the flow rate, and the slurry temperature.

In addition, a CMP apparatus disclosed in Patent Literature 2 includes a platen body formed of a three-dimensional porous body, and a decompression pump, in which the decompression pump decompresses the platen body to suck and remove the air layer between a polishing side surface of the platen body and a polishing pad attachment surface so as to perform adsorption and holding, thereby providing a high flatness precision of a polishing pad holding platen.

### Citation List

### Patent Literature

Patent Literature 1: Japanese Patent Publication 2001-291690

Patent Literature 2: Japanese Patent Publication 2018-51702

### SUMMARY OF INVENTION

### Technical Problem

In such a polishing processing apparatus, there is a problem that when the relative speed and pressure between a surface of wafer that is a target of polishing (hereinafter referred to as the “surface to be polished”) and a polishing pad are not uniform over the entire surface of the surface to be polished, uneven polishing such as insufficient polishing or overpolishing occurs.

For example, in conventional CMP apparatuses, the prevention of thermal deformation of a polishing platen, which is a fundamental item in realizing uniform static pressure distribution, is handled by using expensive low-expansion materials and sophisticated and complex temperature control. Therefore, it was difficult to take a countermeasure that use a low-cost general steel material, and to perform flatness management of a polishing platen without sophisticated temperature control.

The main reason for this is the lack of improvement in a water cooling mechanism of the polishing platen. Thermal deformation of the platen is mainly generated from two factors. In conventional mechanisms, a satisfactory solution cannot be obtained by cooling a bottom portion of the polishing platen alone, and there is a need for mechanical consideration. A specific description will be given below.

The first factor of the thermal deformation of a polishing platen is the temperature difference in the plate thickness direction of the polishing platen. In addition, the second factor of the thermal deformation of the polishing platen is a case where the thermal expansion in the diameter direction of a disk is restrained.

FIG. 9 is an explanatory diagram simply illustrating the relationship between the outer diameter and the thermal expansion displacement in a case where a central portion of a polishing platen is convexly deformed by 0.2 [mm]. It should be noted that Z illustrated in the figure is convex displacement. X is the diameter of the polishing platen. ΔX is the thermal expansion displacement. L is X+ΔX.

As shown in the graph and schematic diagrams illustrated in FIG. 9, it can be seen that when the outer diameter of the polishing platen is increased, the polishing platen central portion is greatly deformed even with small thermal expansion displacement.

In addition, in conventional CMP apparatuses, as illustrated in FIG. 10, generally, water-cooling grooves of a rear surface of a polishing platen (polishing platen B) are cast structures, and a mechanism is used in which a polishing platen B outer periphery portion and a lower cooling plate are forcibly restrained by bolt fastening or the like. In the case of such a mechanism, for example, a polishing platen A is subject to the influence of a polishing platen B surface being irregularly deformed, and the shape of a surface of the polishing platen A will also be deformed.

In addition, in CMP apparatuses, the chemical reaction temperature of a slurry at a polishing pad portion is required to be around 30 [° C], and cooling water is adapted to room temperature. There remains a problem that it is necessary to take a measures capable of minimizing the deformation (thermal deformation) of a polishing platen under these environmental conditions.

A main object of the present invention is to provide a polishing processing apparatus capable of effectively preventing deformation (thermal deformation) of a polishing platen of a CMP apparatus, further improving the SFOR of a substrate surface and the like, and stably performing polishing processing for a large number of pieces with high quality. In addition, a polishing table is provided.

### Solution to Problem

The present invention is a polishing processing apparatus that includes a polishing table including a polishing pad, and a polishing head that holds a substrate to be polished to bring a surface to be polished thereof to come into sliding contact with the polishing pad, in which the polishing table includes a polishing platen having a surface on which the polishing pad is disposed, a cooling base on which the polishing platen is placed, and that has first grooves formed in a surface that contacts a rear surface of the polishing platen, and a decompression cooling mechanism that supplies a temperature-controlled negative pressure fluid to the first grooves of the cooling base to simultaneously perform suction and cooling of the polishing platen, collects the negative pressure fluid that has passed through the first grooves to perform chiller treatment, and supplies the negative pressure fluid to the first grooves again, and the decompression cooling mechanism includes generating means for generating the negative pressure fluid, temperature control means for performing chiller treatment of the negative pressure fluid, and supplying means for supplying the negative pressure fluid whose temperature has been controlled by the temperature control means to the first grooves.

A polishing table for a polishing processing apparatus that includes the polishing table including a polishing pad, and a polishing head that holds a substrate to be polished to bring a surface to be polished thereof to come into sliding contact with the polishing pad, in which the polishing table includes a polishing platen having a surface on which the polishing pad is disposed, a cooling base on which the polishing platen is placed, and that has first grooves formed in a surface that contacts a rear surface of the polishing platen, and a decompression cooling mechanism that supplies a temperature-controlled negative pressure fluid to the first grooves of the cooling base to simultaneously perform suction and cooling of the polishing platen, collects the negative pressure fluid that has passed through the first grooves to perform chiller treatment, and supplies the negative pressure fluid to the first grooves again, and the decompression cooling mechanism includes generating means for generating the negative pressure fluid, temperature control means for performing chiller treatment of the negative pressure fluid, and supplying means for supplying the negative pressure fluid whose temperature has been controlled by the temperature control means to the first grooves.

### Advantageous Effects of Invention

According to the present invention, it is possible to provide a polishing processing apparatus capable of effectively preventing deformation (thermal deformation) of a platen (polishing platen) of a CMP apparatus, further improving the SFOR of a substrate surface and the like, and stably performing polishing processing for a large number of pieces with high quality. In addition, a polishing table can be provided.

### BRIEF DESCRIPTION OF DRAWINGS

FIG. 1 is a diagram for describing an example of a polishing head included in a polishing processing apparatus according to the present embodiment and its periphery configuration.

FIG. 2 is a schematic longitudinal cross-sectional view for describing an example of the periphery configuration of a polishing table including a polishing platen and a cooling base according to the present embodiment.

FIG. 3 is a diagram for describing an example of first grooves formed in a surface of the cooling base.

FIG. 4 is a diagram for describing an example of second grooves formed in a rear surface of the cooling base.

FIG. 5 is a perspective view illustrating an example of the first grooves (the second grooves).

FIG. 6 is a diagram for describing an example of the main configuration of a decompression cooling mechanism according to the present embodiment.

FIG. 7 is a flowchart for describing an example of a main control procedure by a control unit at the time of performing polishing.

FIG. 8 is a schematic diagram illustrating comparison between (a) the case of a configuration with water cooling only and (b) the case of a configuration with decompression cooling.

FIG. 9 is an explanatory diagram simply illustrating the relationship between the outer diameter and the thermal expansion displacement in a case where a polishing platen central portion is convexly deformed by 0.2 [mm].

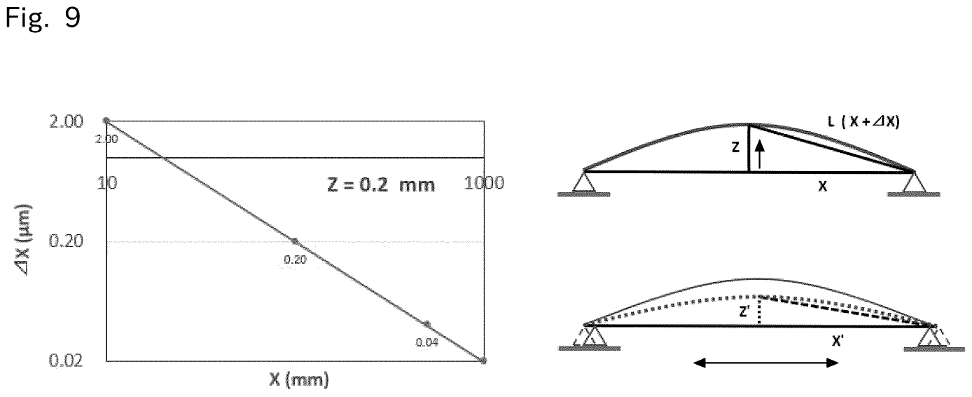

FIG. 10 is a schematic longitudinal cross-sectional view for describing an example of a polishing platen in a conventional CMP apparatus and its periphery configuration.

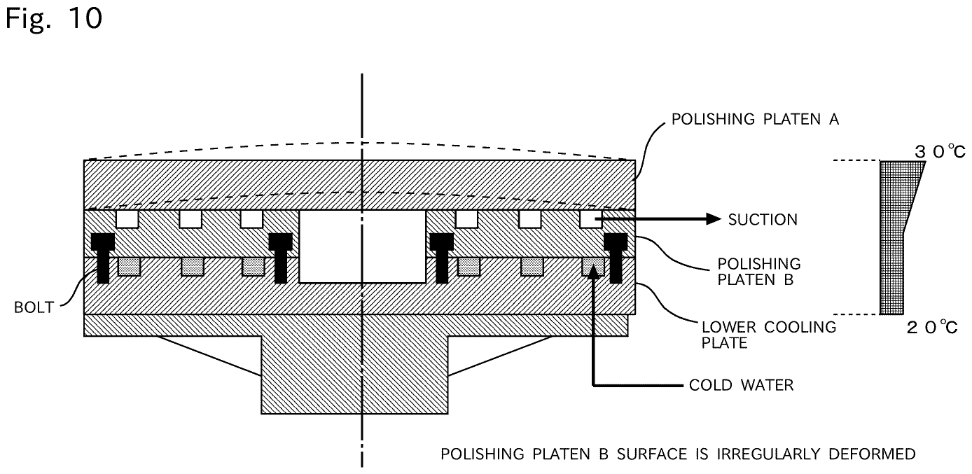

### DESCRIPTION OF EMBODIMENTS

Hereinafter, embodiments of the invention will be described with reference to the drawings. It should be noted that a polishing processing apparatus of the present embodiment polishes a substrate (hereinafter may be referred to as a wafer) such as a semiconductor wafer or a glass substrate. In this description, one surface of this substrate is referred to as a circular or substantially circular surface to be polished. In addition, a surface of a polishing pad that contacts the surface to be polished of a wafer is referred to as a polishing surface.

The polishing processing apparatus has a polishing pad, which serves as a polishing member, attached thereto, and includes a polishing table for horizontally rotating the polishing pad, and a polishing head for bringing a surface to be polished of a substrate to face and come into sliding contact with the polishing pad.

The substrate is pressed against the polishing pad by the polishing head. Then, polishing processing of the surface to be polished is performed by rotating the polishing table and the polishing head while supplying polishing liquid (slurry) to the polishing pad.

### Embodiments

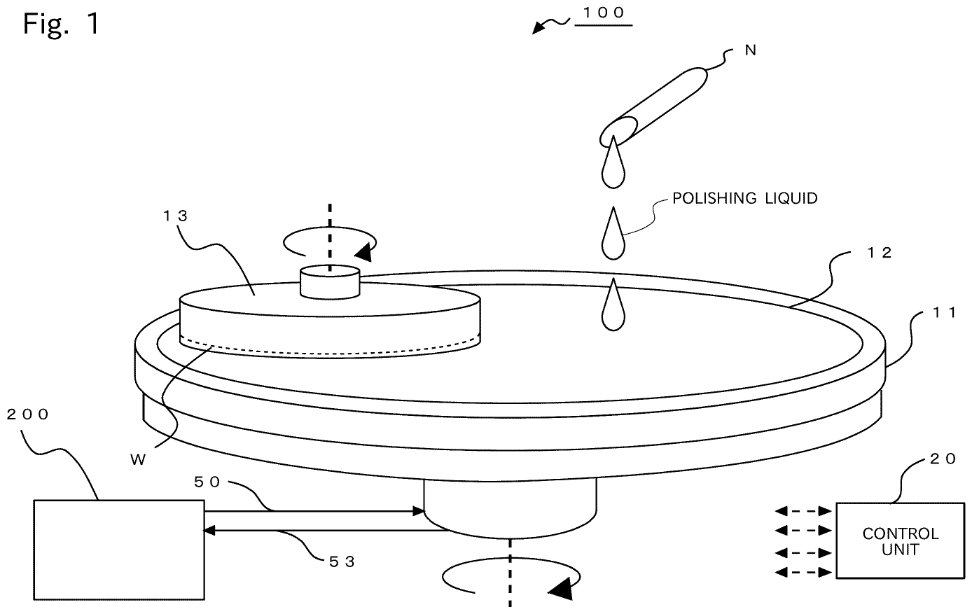

FIG. 1 is a diagram for describing an example of a polishing head included in a polishing processing apparatus 100 according to the present embodiment and its periphery configuration.

The polishing processing apparatus 100 illustrated in FIG. 1 includes a polishing table 11, and a polishing pad 12 is attached to a surface portion of the polishing table 11. In addition, the polishing processing apparatus 100 includes a decompression cooling mechanism 200.

The polishing processing apparatus 100 further includes a polishing head 13 that holds a substrate (wafer) W to press a surface to be polished thereof against the polishing pad 12, a nozzle N for supplying polishing liquid toward the polishing pad 12, a motor (illustration omitted) for horizontally rotating each of the polishing table 11 and the polishing head 13, a polishing liquid supplying mechanism (illustration omitted) connected to the nozzle N, and a control unit 20 including a computer for controlling each of driving units including the motor.

The polishing pad 12 has a disc-like shape, and the radius thereof is larger than the maximum diameter (diameter) of the surface to be polished of the wafer W. This mechanism can change the rotation frequency and rotation direction of each of the polishing pad 12 and the polishing head 13, and adjust the relative polishing speed within a surface of the wafer W.

In addition, the polishing pad 12 itself has elasticity, and a commercially available material, such as a polishing pad made of nonwoven fabric or a polishing pad made of urethane foam, can be used.

The polishing head 13 includes a holding mechanism that holds the wafer W such that the surface to be polished thereof come into sliding contact with the polishing pad 12, and a pressing mechanism that applies pressure to the held wafer W from a rear surface direction (rear surface side) of the surface to be polished thereof toward the polishing pad 12.

The control unit 20 mainly performs positioning of the nozzle N, controlling the start or stop of supply of the polishing liquid from the nozzle N, controlling the supply amount per unit time of the polishing liquid sprayed and supplied from the nozzle N, controlling the start or stop of activation of the motor, and the like. The rotational force of the motor controlled by the control unit 20 is transmitted to the polishing table 11 via a driving unit that is not illustrated. This causes the polishing table 11 to rotate horizontally or to stop rotation.

The rotational force (torque) of the motor is also transmitted to the polishing head 13 via a driving unit (for example, a universal joint) that is not illustrated. This causes the polishing head 13 to rotate horizontally or to stop rotation.

It is common that the rotation direction of the polishing table 11 and the rotation direction of the polishing head 13 are the same direction. This is because, when they are in the opposite directions, there is a risk that the polishing relative velocity within a wafer surface becomes uneven, and equal amount polishing cannot be performed. The polishing accuracy can be increased by setting the rotation direction of the polishing table 11 and the rotation direction of the polishing head 13 to the same direction, and adjusting the rotation speeds of both.

It should be noted that the rotational force of a single motor may be transmitted to the polishing table 11 and the polishing head 13 via gears each having a different gear ratio, or rotational forces may be transmitted through individual motors, respectively. Both can be arbitrarily designed. The procedures of various kinds of control by the control unit 20 will be described later.

The polishing liquid is supplied from the nozzle N toward the polishing pad 12 for a predetermined time period in a state where the rotation speed of the polishing table 11 has reached a predetermined value under the control of the control unit 20.

The decompression cooling mechanism 200 simultaneously performs suction and cooling of a polishing platen 1 by supplying temperature-controlled negative pressure fluid to first grooves 21 of a cooling base 2 that will be described later. In addition, the negative pressure fluid that has passed through the first grooves 21 of the cooling base 2 is collected and processed, and is supplied to the first grooves 21 again.

It should be noted that the operation of the decompression cooling mechanism 200 is mainly controlled by the control unit 20.

In addition, the decompression cooling mechanism 200 performs cooling of the cooling base 2 and a lower base 3 by supplying the temperature-controlled negative pressure fluid to second grooves 22 of the cooling base 2 that will be described later. In addition, the negative pressure fluid that has passed through the second grooves 22 of the cooling base 2 is collected and processed, and is supplied to the second grooves 22 again. Details will be described later.

Next, a detailed description will be given of the configurations of the polishing table 11 and the decompression cooling mechanism 200 included in the polishing processing apparatus 100.

### Configuration of Polishing Table

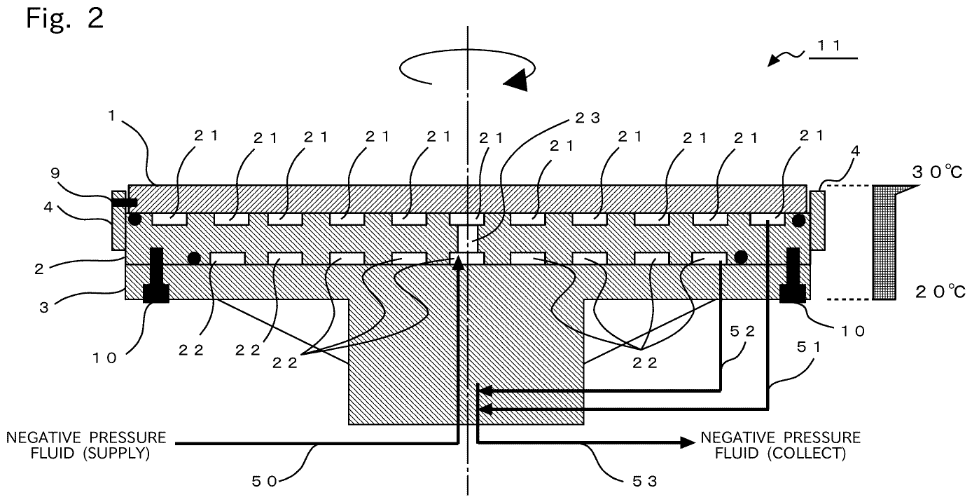

FIG. 2 is a schematic longitudinal cross-sectional view for describing an example of the periphery configuration of a polishing table including a polishing platen and a cooling base.

A polishing table 11 illustrated in FIG. 2 is constituted by including a polishing platen 1, a cooling base 2, the lower base 3, and a supporting tool 4.

The polishing platen 1 is a platen that is formed into a cylindrical shape having a predetermined height (thickness), and is configured such that the aforementioned polishing pad 12 is pasted (disposed) on a surface thereof.

The cooling base 2 is a base that is formed into a cylindrical shape having a predetermined height (thickness). The polishing platen 1 is placed on a surface of the cooling base 2, and the surface of the cooling base 2 and a rear surface of the polishing platen 1 are configured to be in contact with each other.

In addition, the cooling base 2 is placed on the lower base 3, and a rear surface of the cooling base 2 and a surface of the lower base 3 are configured to be in contact with each other.

In the cooling base 2, the first grooves 21 are formed in the surface of the cooling base 2 that is in contact with the rear surface of the polishing platen 1. It should be noted that the details of the configuration of the first grooves 21 will be described later.

The first grooves 21 are connected to the decompression cooling mechanism 200 via a pipe 50 (a pipe that supplies the temperature-controlled negative pressure fluid). In addition, the first grooves 21 are connected to the decompression cooling mechanism 200 via a pipe 51 (a pipe that collects the negative pressure fluid).

The second grooves 22 are formed in the rear surface of the cooling base 2. £ It should be noted that the details of the configuration of the second grooves 22 will be described later.

The second grooves 22 are connected to the decompression cooling mechanism 200 via the pipe 50 (the pipe that supplies the temperature-controlled negative pressure fluid). In addition, the second grooves 22 are connected to the decompression cooling mechanism 200 via a pipe 52 (a pipe that collects the negative pressure fluid).

The lower base 3 is configured such that the cooling base 2 is placed thereon, and the polishing platen 1 is placed thereon via the cooling base 2. Specifically, for the lower base 3 and the cooling base 2, for example, the cooling base 2 is connected to the lower base 3 via connection tools such as bolts 10.

The supporting tool 4 is a ring formed into an annular shape with a predetermined height, and prevents the polishing platen 1 from jumping out in a horizontal direction due to the rotational force of the polishing table 11.

As illustrated in FIG. 2, the supporting tool 4 is formed to have an inner diameter size and a height that cover a part or all of the outer periphery surface direction of the polishing platen 1 and the cooling base 2 in a state where the polishing platen 1 is placed on the cooling base 2.

In this manner, the supporting tool 4 functions as prevention means for preventing the polishing platen 1 from jumping out in the horizontal direction due to the rotational force of the polishing table 11.

It should be noted that when the inner diameter size of the supporting tool 4 is relatively increased relative to the outer diameter size of the polishing platen 1, the forced restraint of the outer periphery portion of the polishing platen 1 will be released.

Accordingly, even when the size change (thermal deformation) in the diameter direction of the polishing platen 1 occurs due to the frictional heat (slurry reaction temperature) between the wafer W and the polishing pad 12 generated during polishing processing, it becomes possible to prevent “deflection” that occurs upward in a central region of the polishing platen 1.

Therefore, the deformation (thermal deformation) of the platen (the polishing platen 1) of the CMP apparatus can be effectively prevented, and further improvement in the SFOR of a substrate surface and the like can be achieved. That is, it becomes possible to avoid convex deformation caused by the thermal expansion of the polishing platen in the diameter direction being restrained, which is the second factor of the thermal deformation of the polishing platen.

It should be noted that, for the lower base 3, as described above, the rotational force of the motor controlled by the control unit 20 is transmitted to the lower base 3 via the driving unit that is not illustrated. The rotational force transmitted to the lower base 3 is transmitted to the cooling base 2, and is further transmitted to the polishing platen 1 via the cooling base 2 and a pin 9 of the supporting tool 4. That is, although the polishing platen 1 is not restrained in the diameter direction, the rotational force of the cooling base 2 is transmitted via the pin 9.

This causes the polishing table 11 including the polishing platen 1 and the cooling base 2 to rotate integrally and horizontally, or to stop rotation.

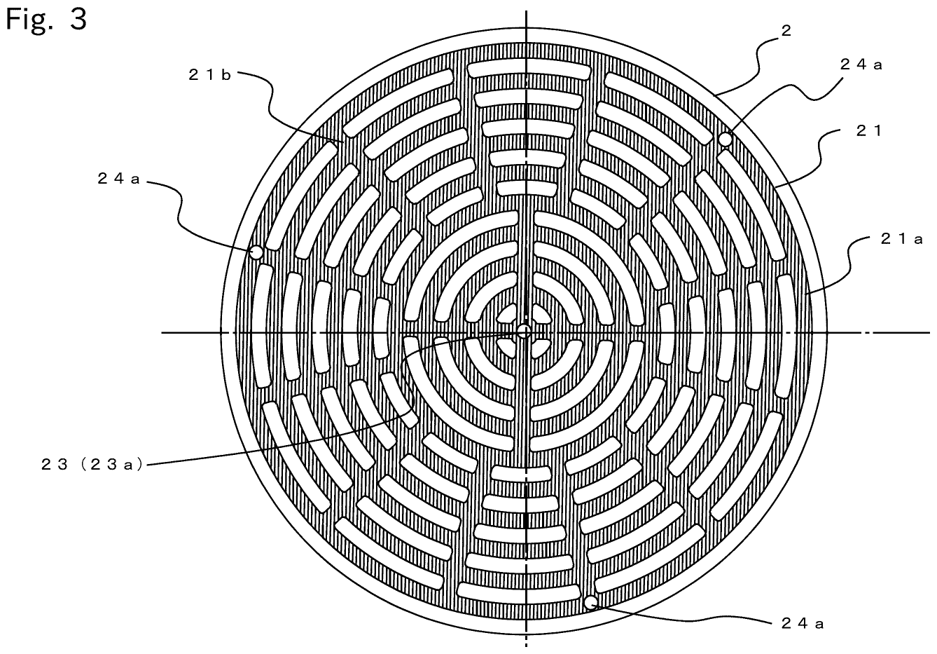

FIG. 3 is a diagram for describing an example of the first grooves 21 formed in the surface of the cooling base 2.

The first grooves 21 (a shaded area in FIG. 3) formed in the surface of the cooling base 2 are formed by including a plurality of annular grooves 21a formed concentrically, and radial grooves 21b that connect each of the annular grooves. Fluid is supplied to the first grooves 21.

A communication hole 23 illustrated in FIG. 3 is a hole that connects the groove in a center portion of the first groove 21 formed in the surface of the cooling base 2 to the groove in a center portion of the second grooves 22 formed in the rear surface of the cooling base.

It should be noted that whether or not to provide the communication hole 23 can be arbitrarily set. For example, flow channels can also be configured such that each of the supply of the fluid to the first grooves 21 and the supply of the fluid to the second grooves 22 can be independently performed.

It should be noted that the supply and collection of the temperature-controlled negative pressure fluid to and from the first grooves 21 by the decompression cooling mechanism 200 are configured such that, for example, the temperature-controlled negative pressure fluid is supplied from a substantially center position (the communication hole 23 or a hole 23a that will be described later) of the first grooves 21, and the negative pressure fluid is collected from outer periphery positions (holes 24a) of the first grooves 21.

In addition, although FIG. 3 illustrates an example in which three circular holes 24a are formed, the number and shape of the holes 24a are not limited to these.

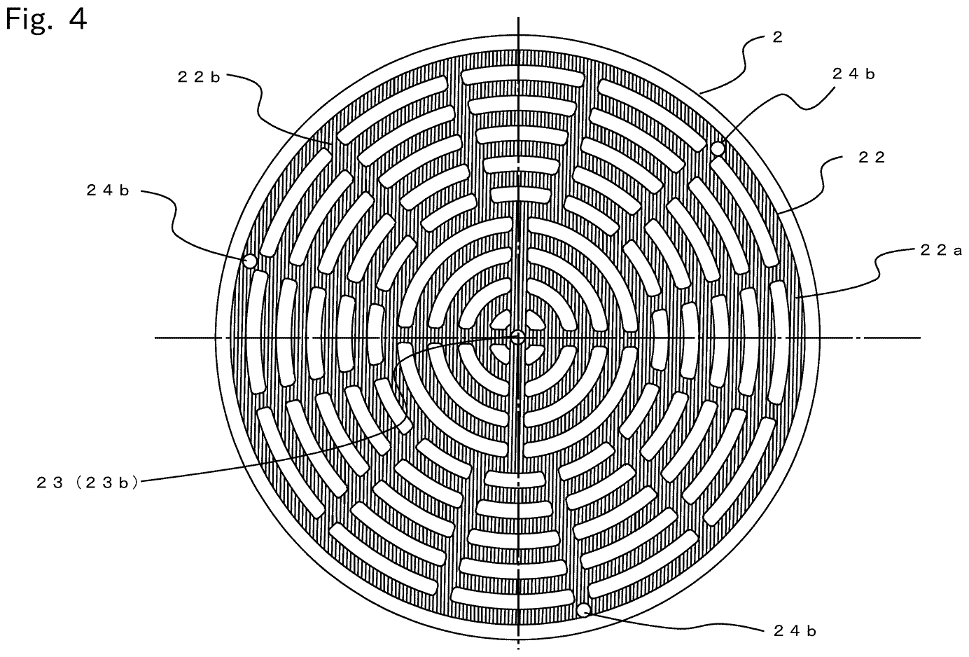

FIG. 4 is a diagram for describing an example of the second grooves 22 formed in the rear surface of the cooling base.

The second grooves 22 (a shaded area in FIG. 4) formed in the rear surface of the cooling base 2 is formed by including a plurality of annular grooves 22a formed concentrically, and radial grooves 22b that connect each of the annular grooves.

The communication hole 23 illustrated in FIG. 3 and FIG. 4 is the hole that connects the groove in the center portion of the second grooves 22 formed in the rear surface of the cooling base 2 to the groove in the center portion of the first groove 21 formed in the surface of the cooling base 2. It should be noted that whether or not to provide the communication hole 23 can be arbitrarily set.

For example, flow channels can also be configured such that the supply of the temperature-controlled negative pressure fluid to the first grooves 21 is performed via the hole 23a that supplies the temperature-controlled negative pressure fluid only to the first grooves 21, the supply of the temperature-controlled negative pressure fluid to the second grooves 22 is performed via a hole 23b that supplies the temperature-controlled negative pressure fluid only to the second grooves 22, and each supply can be independently performed.

It should be noted that the supply and collection of the temperature-controlled negative pressure fluid to and from the second grooves 22 by the decompression cooling mechanism 200 are configured such that, for example, the temperature-controlled negative pressure fluid is supplied from a substantially center position (the communication hole 23) of the second grooves 22, and the negative pressure fluid is collected from outer periphery position (holes 24b) of the second grooves 22.

In addition, although FIG. 4 illustrates an example in which three circular holes 24b are formed, the number and shape of the holes 24b are not limited to these.

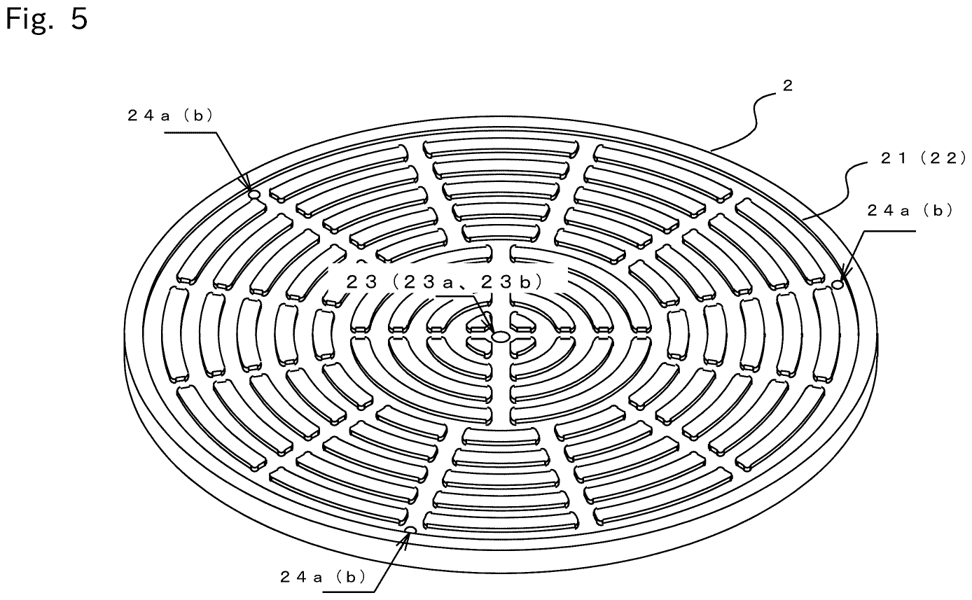

FIG. 5 is a perspective view illustrating an example of the first grooves 21 (the second grooves 22). It is an example in which the groove configurations of the first grooves 21 and the second grooves 22 described above are the same configuration, and the positional relationship of each hole can be seen.

It should be noted that when the supply of the temperature-controlled negative pressure fluid is performed from the center portion of the cooling base 2, and the collection of the negative pressure fluid is performed from the outer periphery positions of the cooling base 2, the supply/collection can be efficiently performed by utilizing the rotational force of the table 11 during the polishing, and the action of the centrifugal force generated by the rotation.

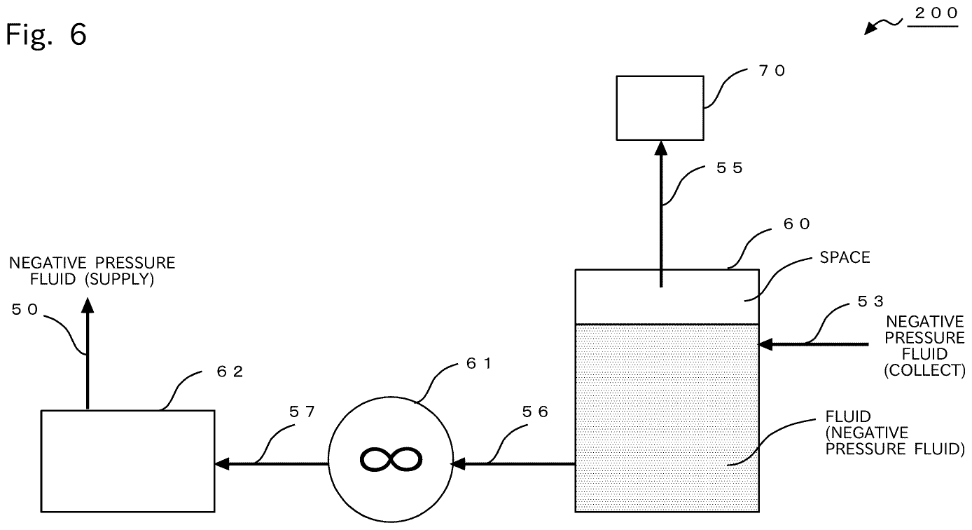

FIG. 6 is a diagram for describing an example of the main configuration of the decompression cooling mechanism 200. The decompression cooling mechanism 200 is constituted by including a tank 60 that stores fluid (for example, water), a fluid pump 61 that pumps the fluid, a chiller device 62 that cools the fluid, and a vacuum pump 70.

A predetermined amount of the fluid (for example, water) is stored in the tank 60. The predetermined amount is, for example, an amount of fluid that fills the first grooves 21 and the second grooves 22 of the cooling base 2, and that sufficiently fills the flow channels of the fluid during the process from supply to recovery, and prevents gas (for example, air) from being mixed in.

In addition, the tank 60 is formed to have a storage size such that the tank 60 does not become full even when the aforementioned sufficient amount of fluid is stored therein. That is, as illustrated in FIG. 6, the tank 60 is configured such that a predetermined space is formed in an upper portion of the tank 60.

As illustrated in FIG. 6, the vacuum pump 70 is connected to the upper space of the tank 60 via a pipe 55. The vacuum pump 70 is for discharging the gas in a container of the tank 60 in order to maintain the inside of the container at a low pressure (vacuum) equal to or less than atmospheric pressure. The fluid stored in the tank 60 becomes a negative pressure fluid by the tank 60 and the vacuum pump 70. In this manner, the tank 60, the vacuum pump 70, and the like function as generating means for generating the negative pressure fluid.

With the decompression effect obtained by generating the negative pressure fluid and supplying the negative pressure fluid to the first grooves 21 of the cooling base 2 as described above, the polishing platen 1 placed on the cooling base 2 is absorbed onto the surface of the cooling base 2.

The fluid pump 61 takes in the negative pressure fluid in the tank 60 via a pipe 56, and transports the negative pressure fluid that has been taken in toward the chiller device 62 via a pipe 57.

The chiller device 62 performs chiller treatment that controls the temperature of (for example, cools) the negative pressure fluid supplied via the fluid pump 61 to be a desired temperature. In this manner, the chiller device 62 functions as temperature control means for performing chiller treatment on the negative pressure fluid to control the temperature of (for example, cool) the negative pressure fluid.

It should be noted that, as an example of the temperature control performed by the chiller device 62, the temperature of the negative pressure fluid is controlled so that the surface temperature of the polishing platen 1 during the polishing is maintained at approximately 30 [C].

For example, the negative pressure fluid that has passed through the first grooves 21 and the second grooves 22 is collected in a state where the temperature has become relatively high with respect to the temperature during the supply due to heat generated during the polishing. In this case, the chiller device 62 performs the processing for cooling the collected negative pressure fluid to the temperature as described above.

Furthermore, the fluid pump 61 supplies the temperature-controlled negative pressure fluid toward the first grooves 21 and the second grooves 22 of the cooling base 2 via the chiller device 62 and the pipe 50.

In this manner, the fluid pump 61 functions as supplying means for supplying the negative pressure fluid whose temperature has been controlled by the chiller device 62 to the first grooves 21 of the cooling base 2.

In addition, the fluid pump 61 also functions supplying means for supplying the negative pressure fluid whose temperature has been controlled by the chiller device 62 to the first grooves 21 and the second grooves 22 of the cooling base 2.

As described above, the decompression cooling mechanism 200 is a mechanism for supplying the temperature-controlled negative pressure fluid to the first grooves 21 of the cooling base 2 so that suction and cooling of the polishing platen 1 can be simultaneously performed.

In addition, the decompression cooling mechanism 200 collects and processes the negative pressure fluid that has passed through the first grooves of the cooling base 2 to supply the negative pressure fluid to the first grooves 21 again. It should be noted that this processing is the step of generating the temperature-controlled negative pressure fluid mentioned previously.

In addition, the decompression cooling mechanism 200 can also be configured to be able to supply the temperature-controlled negative pressure fluid to the first grooves 21 of the cooling base 2 to simultaneously perform suction of the polishing platen 1 and cooling of the polishing platen 1 and the cooling base 2, and to supply the temperature-controlled negative pressure fluid to the second grooves 22 to perform cooling of the cooling base 2 and the lower base 3.

In addition, the negative pressure fluid that has passed through the first grooves 21 or the second grooves 22 of the cooling base 2 is collected and processed, and is supplied to the first grooves 21 or the second grooves 22 again. It should be noted that this processing is the step of generating the temperature-controlled negative pressure fluid mentioned previously.

### Control Procedure of Polishing

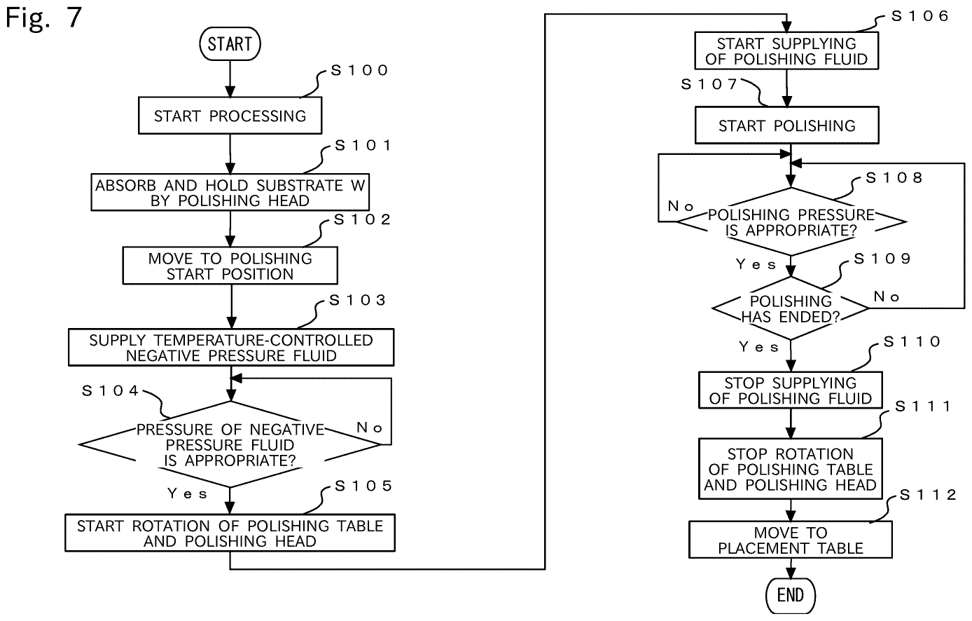

Next, a polishing procedure by the polishing processing apparatus 100 of the present embodiment will be described. FIG. 7 is a flowchart for describing an example of a main control procedure by the control unit 20 at the time of performing polishing. The control unit 20 starts control in response to reception of an input of a start instruction by an operator of the polishing processing apparatus 100 (S100). After predetermined initial processing, holding of the wafer W by the polishing head 13 is started (S101).

The control unit 20 holds the wafer W from a wafer delivery table (not illustrated), and moves the polishing head 13 to a starting position of polishing (S102).

The control unit 20 supplies the temperature-controlled negative pressure fluid to the first grooves 21 (the second grooves 22) of the cooling base 2 via the decompression cooling mechanism 200 (S103).

The control unit 20 also determines whether or not an appropriate pressure is applied to the negative pressure fluid, and whether or not a suction pressure is appropriate via a sensor that is not illustrated (S104).

When the control unit 20 determines that the pressure is appropriate (S104: Yes), the control unit 20 issues an instruction to a motor that is not illustrated, so as to start rotation of the polishing table 11 and the polishing head 13 (S105). Accordingly, the polishing table 11 and the polishing head 13 start rotation horizontally.

It should be noted that the control unit 20 continuously controls the decompression cooling mechanism 200 such that, from the start to the end of polishing, the decompression cooling mechanism 200 supplies the temperature-controlled negative pressure fluid to the first grooves 21 of the cooling base 2 to simultaneously perform suction of the polishing platen 1 and cooling of the polishing platen 2 and the cooling base 1, and also, collects and processes the negative pressure fluid that has passed through the first grooves 21 or the second grooves 22 of the cooling base 2, and supplies the negative pressure fluid to the first grooves 21 In addition, the control unit 20 can also be configured to continuously control the decompression cooling mechanism 200 such that, from the start to the end of polishing, the decompression cooling mechanism 200 supplies the temperature-controlled negative pressure fluid to the first grooves 21 and the second grooves 22 of the cooling base 2 and, simultaneously performs suction of the polishing platen 1 and cooling of the polishing platen 2 and the cooling base 1 by supplying the temperature-controlled negative pressure fluid to the first grooves 21, and also, collects and processes the negative pressure fluid that has passed through the first grooves 21 or the second grooves 22 of the cooling base 2, and supplies the negative pressure fluid to the first grooves 21 and the second grooves 22 again.

After issuing the instruction to start rotation of the polishing table 11 and the polishing head 13, the control unit 20 issues an instruction for positioning of the nozzle N, and issues an instruction to start supplying of polishing liquid to the polishing liquid supplying mechanism (S106). Accordingly, the polishing liquid is supplied from the nozzle N toward the surface of the polishing pad 12. In this manner, the control unit 20 starts polishing (S107).

The control unit 20 determines whether or not the polishing pressure is appropriate (S108). When it is determined to be appropriate (S108: Yes), the control unit 20 proceeds to the processing in step S109. Otherwise (S108: No), the control unit 20 adjusts the polishing pressure and returns to the processing in step S108.

The control unit 20 determines whether or not polishing has ended (S109). This determination is based on, for example, a detection result of a sensor, and the polishing ends when it is determined that the wafer W has been polished to a desired thickness.

When the control unit 20 determines that the polishing has not ended (S109: No), the control unit 20 returns to the processing in step S108. In addition, when the control unit 20 determines that the polishing has ended (S109: Yes), the control unit 20 issues an instruction to stop supplying of the polishing liquid to the polishing liquid supplying mechanism (S110).

Then, the control unit 20 issues an instruction to the motor to stop rotation of the polishing table 11 and the polishing head 13 (S111). Then, the polishing head 13 is moved to a table on which the wafer W after the polishing is to be placed (S112). Accordingly, a series of polishing processing ends.

As described above, it becomes possible to reduce, by the decompression suction effects by the decompression cooling mechanism 200, the thermal deformation of the polishing platen 1 (the size change of the polishing platen 1) due to the temperature difference in the plate thickness direction caused by the frictional heat (the slurry reaction heat) between the wafer W and the polishing pad 12 generated during polishing processing. In addition, it becomes possible to reduce the thickness of the polishing platen 1 by the simultaneous effects of water cooling and decompression suction.

Therefore, the deformation (thermal deformation) of the platen (the polishing platen 1) of the CMP apparatus can be effectively prevented, and further improvement in the SFOR of a substrate surface and the like can be achieved.

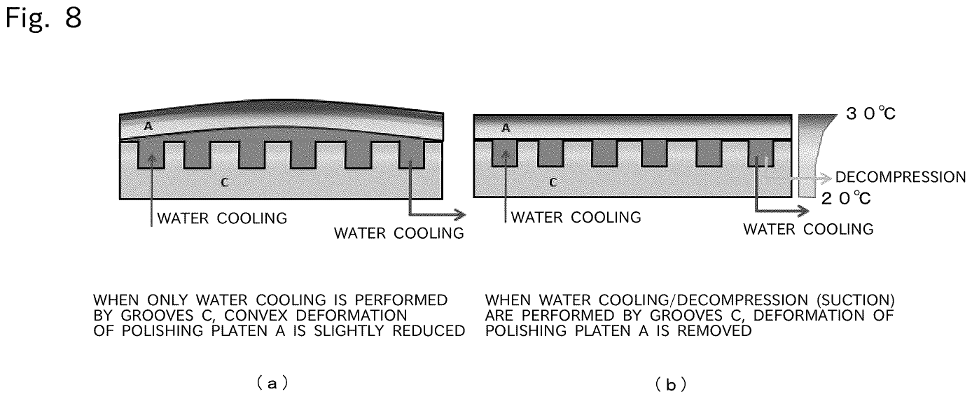

FIG. 8 is a schematic diagram illustrating comparison between (a) the case of water cooling only and (b) the case of decompression cooling by the polishing processing apparatus 100 according to the present embodiment.

In a conventional configuration of FIG. 8 (a), by performing water cooling in grooves C, the convex deformation of a polishing platen A due to the temperature difference in the plate thickness direction of the polishing platen, which is the first factor of the thermal deformation of the polishing platen, is slightly reduced. On the other hand, with the configuration of the polishing processing apparatus 100 according to the present embodiment of FIG. 8 (b), by simultaneously performing water cooling/decompression (suction) in grooves C, the thermal deformation can be removed by decompression suction, and the convex deformation of the polishing platen A does not occur.

As described above, with the polishing processing apparatus 100 according to the present embodiment, even when the thermal expansion of the polishing platen 1 occurs due to the frictional heat (slurry reaction heat) between the wafer W and the polishing pad 12 generated during the polishing processing, it becomes possible to prevent the convex deformation of the polishing platen 1. Accordingly, it becomes possible to address the second factor of the thermal deformation factor of the polishing platen.

In addition, it becomes possible to reduce, by the decompression suction effects by the decompression cooling mechanism 200, the thermal deformation of the polishing platen 1 due to the temperature difference in the plate thickness direction caused by the frictional heat (the slurry reaction heat) between the wafer W and the polishing pad 12 generated during the polishing processing. Accordingly, it becomes possible to address the first factor of the thermal deformation of the polishing platen.

In addition, conventionally, each of water cooling and decompression suction has been operated by an independent mechanism, it becomes possible to reduce the thickness of the polishing platen 1 by the simultaneous effects of water cooling and decompression suction.

Therefore, it is possible to effectively prevent deformation (thermal deformation) of a platen (polishing platen) of a CMP apparatus, further improving the SFQR of a substrate surface and the like, and stably performing polishing processing for a large number of pieces with high quality.

In conventional apparatuses, since a polishing platen and a water cooling unit have an integrated structure, and thermal deformation occurs in a state where there is a plate thickness temperature difference, a flatness of zero is impossible in principle. In addition, a platen forcible deformation mechanism (a surface of a platen is a curved surface) the manufacturing cost of which rises by use of a low-expansion material is required, or a special mechanism that corresponds to irregular changes in the flatness of the platen (corresponds with a convex surface in the beginning of operation, and with a concave surface in the end) is required.

On the other hand, the polishing processing apparatus 100 according to the present embodiment includes the mechanism that simultaneously performs water cooling and decompression suction by the same water cooling grooves. Therefore, the polishing processing apparatus 100 has excellent features such as not requiring sophisticated and complicated control, being stable under irregular conditions, and being adaptable to a large-diameter platen.

The above-described embodiments are for more specifically describing the present invention, and the scope of the present invention is not limited to these examples.

### Reference Signs List

1 . . . polishing platen, 2 . . . cooling base, 3 . . . lower base, 4 . . . supporting tool, 11 . . . polishing table, 12 . . . polishing pad, 13 . . . polishing head, 20 . . . control unit, 21 . . . first groove, 22 . . . second groove, 23 . . . communication hole, 60 . . . tank, 61 . . . fluid pump, 62 . . . chiller device, 70 . . . vacuum pump, 100 . . . polishing processing apparatus, 200 . . . decompression cooling mechanism, N . . . nozzle, and W . . . wafer.

1. A polishing processing apparatus that includes a polishing table including a polishing pad, and a polishing head that holds a substrate to be polished to bring a surface to be polished thereof to come into sliding contact with the polishing pad,
wherein the polishing table includes:
a polishing platen having a surface on which the polishing pad is disposed;
a cooling base on which the polishing platen is placed, and that has first grooves formed in a surface that contacts a rear surface of the polishing platen; and
a decompression cooling mechanism that supplies a temperature-controlled negative pressure fluid to the first grooves of the cooling base to simultaneously perform suction and cooling of the polishing platen, collects the negative pressure fluid that has passed through the first grooves to perform chiller treatment, and supplies the negative pressure fluid to the first grooves again, and
the decompression cooling mechanism includes:
generating means for generating the negative pressure fluid;
temperature control means for performing chiller cooling of the negative pressure fluid; and
supplying means for supplying the negative pressure fluid whose temperature has been controlled by the temperature control means to the first grooves.

2. The polishing processing apparatus according to claim 1,
wherein the cooling base has second grooves formed in a rear surface of the cooling base, and
the decompression cooling mechanism supplies the temperature-controlled negative pressure fluid to the first grooves to simultaneously perform suction of the polishing platen and cooling of the polishing platen and the cooling base,
supplies the temperature-controlled negative pressure fluid to the second grooves to perform cooling of the cooling base, and
collects and performs chiller treatment on the negative pressure fluid that has passed through the first grooves or the second grooves, and supplies the negative pressure fluid to the first grooves or the second grooves again.

3. The polishing processing apparatus according to claim 1,
wherein the first grooves are formed by including a plurality of annular grooves formed concentrically, and radial grooves that connect each of the annular grooves, and
the decompression cooling mechanism supplies the temperature-controlled negative pressure fluid from a substantially center position of the first grooves, and collects the negative pressure fluid that has passed through the first grooves from an outer periphery position of the first grooves.

4. The polishing processing apparatus according to claim 2,
wherein the second grooves are formed by including a plurality of annular grooves formed concentrically, and radial grooves that connect each of the annular grooves, and
the decompression cooling mechanism supplies the temperature-controlled negative pressure fluid from a substantially center position of the second grooves, and collects the negative pressure fluid that has passed through the second grooves from an outer periphery position of the second grooves.

5. The polishing processing apparatus according to any one of claims 1 to 4, comprising:
prevention means for preventing the polishing platen from jumping out in a horizontal direction from the polishing table to which a rotational force is applied, by covering a part or all of an outer periphery surface of the cooling base.

6. The polishing processing apparatus according to claim 5,
wherein the prevention means is formed into an annular body, and an inner circumference size of the annular body is formed to be a size relatively larger than an outer diameter size of the cooling base.

7. A polishing table for a polishing processing apparatus that includes the polishing table including a polishing pad, and a polishing head that holds a substrate to be polished to bring a surface to be polished thereof to come into sliding contact with the polishing pad,
wherein the polishing table includes:
a polishing platen having a surface on which the polishing pad is disposed;
a cooling base on which the polishing platen is placed, and that has first grooves formed in a surface that contacts a rear surface of the polishing platen; and
a decompression cooling mechanism that supplies a temperature-controlled negative pressure fluid to the first grooves of the cooling base to simultaneously perform suction and cooling of the polishing platen, collects the negative pressure fluid that has passed through the first grooves to perform chiller treatment, and supplies the negative pressure fluid to the first grooves again, and
the decompression cooling mechanism includes:
generating means for generating the negative pressure fluid;
temperature control means for performing chiller cooling of the negative pressure fluid; and
supplying means for supplying the negative pressure fluid whose temperature has been controlled by the temperature control means to the first grooves.
